(19) United States
(12) Patent Application Publication
(10) Pub. No.: US 2024/0377461 A1
(43) Pub. Date: Nov. 14, 2024

(54) MANAGEMENT APPARATUS, ENERGY STORAGE APPARATUS, MANAGEMENT METHOD, AND PROGRAM

(71) Applicant: GS Yuasa International Ltd., Kyoto-shi, Kyoto (JP)

(72) Inventor: Tomoshige INOUE, Kyoto-shi, Kyoto (JP)

(21) Appl. No.: 18/691,838

(22) PCT Filed: Sep. 7, 2022
(86) PCT No.: PCT/JP2022/033495

§ 371 Date: Mar. 13, 2024

(30) Foreign Application Priority Data
Sep. 14, 2021 (JP) 2021-149686

(51) Int. Cl. G01R 31/367; G01R 31/3842; G01R 31/389; H01M 10/48; H02J 7/00; H02J 7/35

(52) U.S. Cl. CPC G01R 31/367; G01R 31/3842; G01R 31/389; H01M 10/48; H02J 7/00712; H02J 7/35

(57) ABSTRACT

A management apparatus includes an acquisition unit that acquires a current value and a voltage value of an energy storage device, and a calculation unit that calculates a current limit value along a current limit characteristic of the energy storage device based on internal resistance of the energy storage device and the acquired current value and voltage value.

### CROSS REFERENCE TO RELATED APPLICATIONS

This application is a National Stage Application, filed under 35 U.S.C. § 371, of International Application No. PCT/JP2022/033495, filed Sep. 7, 2022, which international application claims priority to and the benefit of Japanese Application No. 2021-149686, filed Sep. 14, 2021; the contents of both of which are hereby incorporated by reference in their entirety.

### BACKGROUND

### Technical Field

The present invention relates to a management apparatus for an energy storage device, an energy storage apparatus, a management method, and a program.

### Description of Related Art

As a method for charging an energy storage device, constant current constant voltage (CCCV) charge is widely known. The CCCV charge is a method in which charge is performed with constant current (CC) in an initial stage of charge, and switching is made to charge with constant voltage (CV) when an energy storage device reaches a predetermined voltage value.

Patent Document JP 5525862 B2 discloses a battery charger provided with a region for performing charge while reducing charge current between CC charge and CV charge.

### BRIEF SUMMARY

In a case where a region in which to perform charge while reducing charge current is provided between CC charge and CV charge, charge acceptance performance of an energy storage device cannot be sufficiently utilized depending on charge current in the region.

An object of the present disclosure is to provide a technique capable of improving charge acceptance performance of an energy storage device.

A management apparatus according to one aspect of the present disclosure includes an acquisition unit that acquires a current value and a voltage value of an energy storage device, and a calculation unit that calculates a current limit value along a current limit characteristic of the energy storage device based on internal resistance of the energy storage device and the acquired current value and voltage value.

According to the present disclosure, the management apparatus can improve charge acceptance performance of an energy storage device.

### BRIEF DESCRIPTION OF THE FIGURES

FIG. 1 is a diagram illustrating an outline of a solar power generating system.

FIG. 2 is a block diagram illustrating a configuration example of a battery charger and an energy storage apparatus on which a management apparatus according to a first embodiment is mounted.

FIG. 3 is a plan view of an energy storage device (battery).

FIG. 4 is a cross-sectional view taken along line IV-IV of FIG. 3.

FIG. 5 is a diagram describing a concept of a method of calculating a current limit value.

FIG. 6 is a diagram describing a case where a current limit value is calculated using a predetermined coefficient.

FIG. 7 is a diagram describing a case where a current limit value is calculated using a predetermined coefficient.

FIG. 8 is a flowchart illustrating an example of a current limit value calculation processing procedure.

FIG. 9 is a diagram describing a concept of a method of calculating a current limit value in a second embodiment.

FIG. 10 is a flowchart illustrating an example of a current limit value calculation processing procedure in the second embodiment.

FIG. 11 is a diagram describing a concept of a method of calculating a current limit value in a third embodiment.

### DETAILED DESCRIPTION OF VARIOUS EMBODIMENTS

### Claim 1

A management apparatus includes an acquisition unit that acquires a current value and a voltage value of an energy storage device, and a calculation unit that calculates a current limit value along a current limit characteristic of the energy storage device based on internal resistance of the energy storage device and the acquired current value and voltage value.

Here, the “current limit characteristic” means a profile indicating a relationship between a voltage value and a current limit value of an energy storage device.

The “current limit value” means a limit value (upper limit value) of a charge current value of an energy storage device.

The “internal resistance” may be ohmic resistance of an energy storage device, or may be ohmic resistance in consideration of non-ohmic resistance.

The management apparatus uses a current limit characteristic defining a relationship between a voltage value and a current limit value of an energy storage device to calculate a current limit value along the current limit characteristic, that is, a target value. The management apparatus may calculate, for example, a current limit value on a current limit characteristic or a current limit value approximate to a current limit value on a current limit characteristic. A calculated current limit value is transmitted to, for example, an external battery charger. An external battery charger charges an energy storage device in a manner not to exceed a current limit value received from the management apparatus.

The current limit value is calculated based on a current value and a voltage value of an energy storage device at the present (time point of estimation), and internal resistance of the energy storage device stored in advance in, for example, a storage unit of the management apparatus. With respect to a current value and a voltage value at the present, a change in the current value and the voltage value in a case where a current limit value is caused to flow is predicted based on internal resistance of an energy storage device, and a current value (current limit value) by which a predicted current value and voltage value are along a current limit characteristic is obtained. According to the present method, as compared with a case where a value obtained by uniformly adding a predetermined coefficient set in advance to a current value at the present without predicting a change in a current value and a voltage value is calculated as a current limit value, it is possible to reduce deviation between a calculated current limit value and a current limit characteristic. Therefore, charge acceptance performance of an energy storage device can be sufficiently utilized. By the above, while safety of an energy storage device is maintained (while occurrence of abnormal events such as excessive heat generation and electrodeposition is prevented), advanced energy management can be realized by cooperation with a battery charger.

In the management apparatus, the current limit characteristic may include a first region, and a second region in which the current limit value decreases in accordance with increase in a voltage value of the energy storage device, and the calculation unit may calculate the current limit value along the second region of the current limit characteristic.

The first region may be a region where the current limit value is constant regardless of a voltage value of the energy storage device.

Both the first region and the second region may be a region where a voltage value of an energy storage device is lower than voltage during constant voltage (CV) charge in constant current constant voltage (CCCV) charge. The management apparatus decreases the second region of a current limit characteristic, that is, a current limit value in and after constant current (CC) charge according to increase in a voltage value while considering internal resistance. By the above, a timing of decreasing a current limit value can be delayed (a constant current charge region can be expanded) as compared with the conventional method, and charge acceptance performance of an energy storage device can be improved.

In the management apparatus, the calculation unit may calculate, as the current limit value, a value at which the current limit characteristic intersects an estimated current value, which is estimated based on the current value, the voltage value, and the internal resistance by using an equivalent circuit model of the energy storage device.

According to the above configuration, the management apparatus obtains an estimated current value corresponding to a current value and a voltage value of an energy storage device at a time point of estimation by using an equivalent circuit model of the energy storage device. The estimated current value can be easily calculated from internal resistance or the like of an energy storage device obtained in advance from actual measurement data or the like. By calculating an intersection of an estimated current value and a current limit characteristic, it is possible to easily and accurately calculate a current limit value suitable for a state of a current value and a voltage value of an energy storage device at a time point of estimation.

In the management apparatus, the calculation unit may calculate the current limit value based on the internal resistance corresponding to at least one of a charge state and temperature of the energy storage device.

The charge state may be, for example, a state of charge (SOC) of an energy storage device. According to the above configuration, since a current limit value is calculated based on internal resistance corresponding to a charge state or temperature of an energy storage device, a current limit value suitably reflecting a state of the energy storage device can be calculated, and charge acceptance performance can be further improved.

In the management apparatus, the calculation unit may calculate the current limit value based on the internal resistance corrected using a correction coefficient.

The correction coefficient may represent, for example, a speed of increase or decrease of a current limit value. By correcting internal resistance by using the correction coefficient, degree of freedom in calculation of a current limit value is increased.

In the management apparatus, the correction coefficient may be changed according to the current value.

According to the above configuration, by changing a correction coefficient in accordance with a current value at a time point of estimation of an energy storage device, a state of a current value of the energy storage device can be reflected in calculation of a current limit value, and a more suitable current limit value can be calculated.

In the management apparatus, the correction coefficient may be changed based on a result of comparison between the acquired current value and voltage value of the energy storage device and the current limit characteristic of the energy storage device.

A result of comparison between a current value and a voltage value at a time point of estimation of an energy storage device and a current limit characteristic may be, for example, a result of comparison of a magnitude relationship between a current value and a voltage value at a time point of estimation of the energy storage device and a current limit characteristic. By changing a correction coefficient based on a result of comparison between a current value and a voltage value at a time point of estimation of an energy storage device and a current limit characteristic, a state of a current value and a voltage value of the energy storage device can be reflected in calculation of a current limit value, and a more suitable current limit value can be calculated.

An energy storage apparatus includes an energy storage device, and the management apparatus according to any of the above.

In a management method, a computer executes processing of acquiring a current value and a voltage value of an energy storage device, and calculating a current limit value along a current limit characteristic of the energy storage device based on internal resistance of the energy storage device and the acquired current value and voltage value.

A program causes a computer to execute processing of acquiring a current value and a voltage value of an energy storage device, and calculating a current limit value along a current limit characteristic of the energy storage device based on internal resistance of the energy storage device and the acquired current value and voltage value.

Hereinafter, the present disclosure will be specifically described with reference to the drawings illustrating an embodiment of the present disclosure.

### First Embodiment

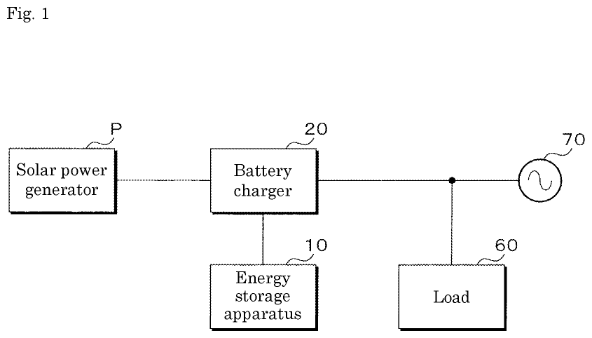

FIG. 1 illustrates an outline of a solar power generating system. The solar power generating system includes a solar power generator P, an energy storage apparatus 10, and a battery charger 20. The solar power generator P converts sunlight into electric power and outputs the electric power. Power generated by the solar power generator P is supplied to a load 60 via the battery charger 20. An excess portion of power generated by the solar power generator P is stored in the energy storage apparatus 10 via the battery charger 20. Instead of the solar power generator P, a power generator (renewable energy power generator) using other renewable energy such as wind power may be used.

The battery charger 20 may be, for example, a power conditioner. The battery charger 20 is connected to each of the solar power generator P, the energy storage apparatus 10, the load 60, and a power system 70 via a power line or the like. The battery charger 20 converts direct current generated by the solar power generator P into alternating current. The battery charger 20 outputs converted alternating current to the power load 60 such as a home electrical appliance or a facility motor (power load). The battery charger 20 also supplies power received from the power system 70 to the load 60 and the energy storage apparatus 10. The energy storage apparatus 10 receives power from the solar power generator P or the power system 70 via the battery charger 20, and stores the received power.

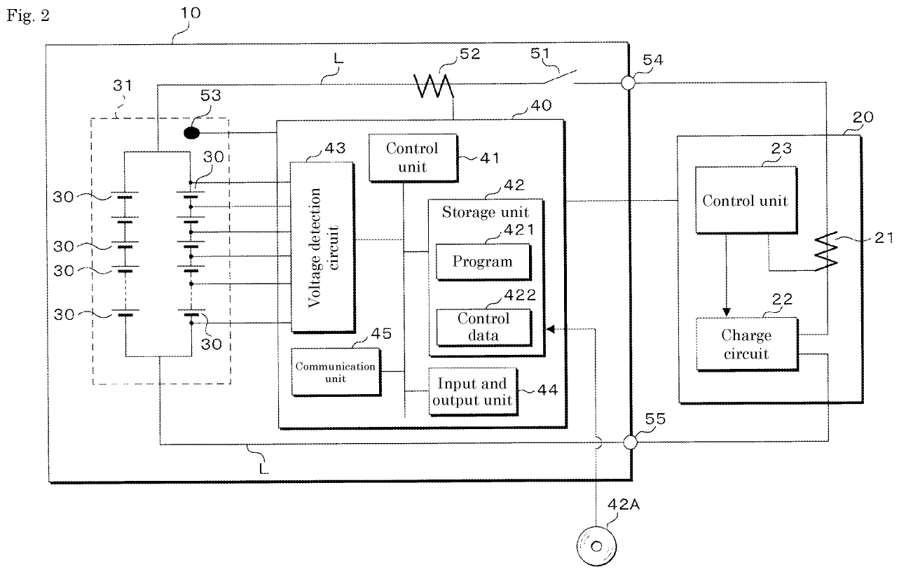

FIG. 2 is a block diagram illustrating a configuration example of the battery charger 20 and the energy storage apparatus 10 on which a management apparatus 40 according to a first embodiment is mounted. As illustrated in FIG. 2, the energy storage apparatus 10 includes an assembled battery 31 including a plurality of secondary batteries (hereinafter, also simply referred to as batteries) 30, a battery management unit (BMU) 40 that manages each of the batteries 30, a current breaker 51, a current measurement resistor 52, and a temperature sensor 53. The BMU 40 is an example of the management apparatus 40. The battery 30 is an example of the energy storage device 30. The battery 30 is, for example, a lithium ion secondary battery. The battery 30 is not limited to an assembled battery, and may be a battery cell. An energy storage device other than a battery may be used. A part of functions of the BMU 40 may be allocated to a monitoring apparatus (for example, CMU: cell monitoring unit) (not illustrated).

The assembled battery 31, the current breaker 51, and the current measurement resistor 52 are connected in series via a current path L. A positive electrode of the assembled battery 31 is connected to an external terminal 54 of a positive electrode via the current measurement resistor 52 and the current breaker 51. A negative electrode of the assembled battery 31 is connected to an external terminal 55 of a negative electrode.

FIG. 2 illustrates an example in which the current measurement resistor 52 is connected to a positive electrode of the assembled battery 31. Alternatively, the current measurement resistor 52 may be connected to a negative electrode of the assembled battery 31.

The current breaker 51 can be configured by a mechanical switch (for example, a relay) or a semiconductor switch such as an FET or a transistor. The current breaker 51 is connected to the BMU 40, and is switched on and off in response to a control signal from the BMU 40. The BMU 40 breaks energization between the assembled battery 31 and the external terminal 54 of a positive electrode by turning off the current breaker 51.

The current measurement resistor 52 is a resistor that measures current of the current path L. The current measurement resistor 52 can measure current of the assembled battery 31 (battery 30) by measuring voltage between both ends of the current measurement resistor 52, that is, voltage corresponding to current of the assembled battery 31 in time series. The current measurement resistor 52 is connected to the BMU 40 and outputs a signal related to the measured current to the BMU 40. Discharge and charge can be determined from polarity (positive or negative) of voltage between both ends of the current measurement resistor 52.

The temperature sensor 53 is arranged in the vicinity of the assembled battery 31, and measures a temperature of the assembled battery 31 or around the assembled battery 31 in time series by a contact manner or a non-contact manner. The temperature sensor 53 is connected to the BMU 40 and outputs a signal related to a detected temperature to the BMU 40.

The BMU 40 includes a control unit 41, a storage unit 42, a voltage detection circuit 43, an input and output unit 44, and a communication unit 45. The BMU 40 acquires measurement data including a voltage value, a current value, and a temperature of the battery 30 as needed, and calculates a current limit value for controlling charge of the battery 30 based on the acquired measurement data.

The control unit 41 is an arithmetic circuit including a central processing unit (CPU), a read only memory (ROM), a random access memory (RAM), and the like. The CPU included in the control unit 41 executes various computer programs stored in the ROM or the storage unit 42 and controls operation of each unit of the hardware described above, so as to cause the entire apparatus to function as the management apparatus of the present disclosure. The control unit 41 may have a function of a timer that measures elapsed time from when a measurement start instruction is given to when a measurement end instruction is given, a counter that counts the number, a clock that outputs date and time information, and the like.

The storage unit 42 is a non-volatile storage device such as a flash memory. The storage unit 42 stores various computer programs and data. A computer program (computer program product) stored in the storage unit 42 includes a program 421 for performing processing related to charge control of the battery 30. Data stored in the storage unit 42 includes control data 422 used in the program 421.

The control data 422 includes, for example, information such as a current limit characteristic according to the battery 30, an equivalent circuit model of the battery 30 used in simulation, and various correction coefficients used for calculation processing. The current limit characteristic is a profile indicating a relationship between voltage of the battery 30 and a current limit value, and is stored as, for example, a function equation indicating the profile. Alternatively, as the current limit characteristic, a curve indicating a profile may be stored, and data of a representative point with which a profile can be drawn by approximation may be stored.

The equivalent circuit model is described with configuration information indicating a circuit configuration, a value of each element constituting the equivalent circuit model, and the like. The storage unit 42 stores configuration information indicating a circuit configuration, a value of each element, and the like. The control unit 41 may acquire information on a current limit characteristic, an equivalent circuit model, and various correction coefficients in advance by communicating with an external device (not illustrated), for example, and store the acquired information in the control data 422. The control data 422 may be updated at predetermined time intervals in consideration of deterioration of the battery 30.

A computer program stored in the storage unit 42 may be provided by a non-transitory recording medium 42A in which the computer program is recorded in a readable manner. The recording medium 42A is a portable memory such as a CD-ROM, a USB memory, or a secure digital (SD) card. The control unit 41 reads a desired computer program from the recording medium 42A by using a reading device (not illustrated), and stores the read computer program in the storage unit 42. Alternatively, the computer program may be provided by communication. The program 421 can be loaded to be executed on a single computer or on a plurality of computers arranged on one site or distributed over a plurality of sites and interconnected by a communication network.

The voltage detection circuit 43 is connected to both ends of each of the batteries 30 via a signal line, and measures voltage between terminals of each of the batteries 30 and total voltage of the assembled battery 31 in time series. The control unit 41 acquires voltage between terminals of each of the batteries 30 and total voltage of the assembled battery 31 through the voltage detection circuit 43.

The input and output unit 44 includes an input and output interface for connecting an external device. The external device connected to the input and output unit 44 includes the current measurement resistor 52 and the temperature sensor 53. The input and output unit 44 receives input of a signal related to current measured by the current measurement resistor 52 and temperature measured by the temperature sensor 53. The control unit 41 acquires current and temperature data through the input and output unit 44. A display device (not illustrated) such as a liquid crystal display may be connected to the input and output unit 44. The control unit 41 outputs a calculation result of a current limit value for the battery 30 from the input and output unit 44 to the display device.

The communication unit 45 includes a communication interface for communicating with the battery charger 20 via a network or the like. The communication unit 45 may be, for example, a wireless communication interface such as WiFi (registered trademark), Bluetooth (registered trademark), 4G, 5G, or the like, or may be a wired communication interface such as CAN. In a case where a calculation result of a current limit value for the battery 30 is obtained, the control unit 41 transmits information based on the calculation result from the communication unit 45 to the battery charger 20. The battery charger 20 receives information transmitted from the communication unit 45, and charges the battery 30 within a range not exceeding a current limit value based on the received information. The communication unit 45 may be communicably connected to an external device such as a personal computer or a smartphone used by the user, an administrator, or the like via a network interface card (not illustrated), and may output information based on a calculation result to the external device. The management apparatus 40 may include a notification unit such as an LED lamp or a buzzer to notify the user of a calculation result.

The battery charger 20 includes a current measurement resistor 21, a charge circuit 22, and a control unit 23. The battery charger 20 is connected to the external terminals 54 and 55 of the energy storage apparatus 10. The control unit 23 is a control device for controlling the current measurement resistor 21 and the charge circuit 22, and includes a CPU, a memory, an input and output interface, a communication interface (all not illustrated), and the like. The control unit 23 controls magnitude of charge current via the charge circuit 22 based on a current limit value received from the BMU 40. The current measurement resistor 21 measures charge current.

FIG. 2 illustrates an example in which the management apparatus is the BMU 40. Alternatively, the management apparatus may be arranged in a place away from the battery 30. The management apparatus may include a server device located away from the battery 30 and communicatively connected to a BMU. A place where calculation of a current limit value is performed is not limited, and may be performed in a server device, for example. In this case, measurement data measured for the battery 30 may be transmitted to the server device by communication.

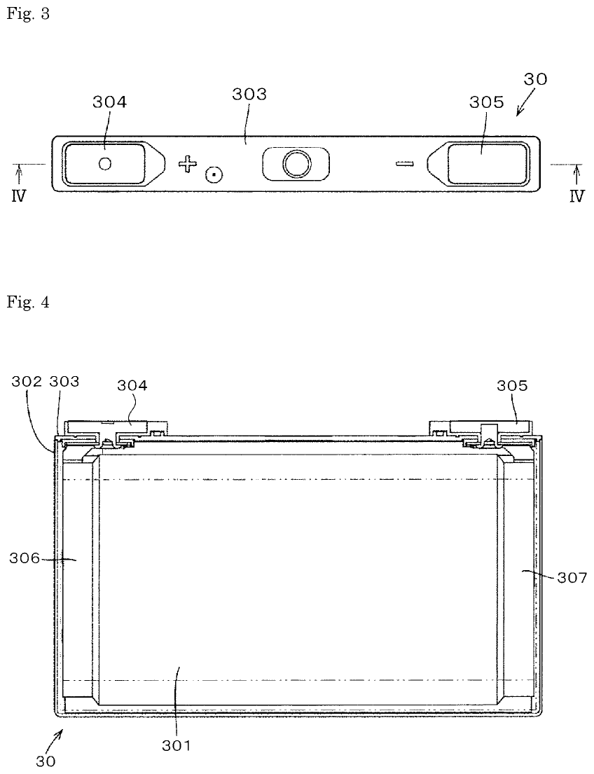

FIG. 3 is a plan view of the energy storage device (battery) 30. FIG. 4 is a cross-sectional view taken along line IV-IV of FIG. 3. A configuration example of the battery 30 will be described with reference to FIGS. 3 and 4. As described above, the battery 30 is, for example, a lithium ion secondary battery. The battery 30 is configured by accommodating a flat-shaped wound electrode assembly 301 and an electrolyte (not illustrated) in a hollow rectangular parallelepiped case 302. A lid portion 303 of the case 302 is provided with a positive electrode terminal 304 and a negative electrode terminal 305 for external connection. 304 and the negative electrode terminal 305 are electrically connected to a positive electrode current collector 306 and a negative electrode current collector 307, respectively. As a material of the case 302, for example, a lightweight metal material having high thermal conductivity such as aluminum is used.

Although not illustrated in detail, the wound electrode assembly 301 is configured by placing a sheet-like positive electrode and negative electrode on each other with two sheet-like separators interposed between them and winding (longitudinally winding or laterally winding) them. The positive electrode and the negative electrode are arranged in a state of being shifted from each other in a width direction of a sheet.

The positive electrode is an electrode plate in which a positive active material layer is formed on a surface of an elongated strip-shaped positive electrode substrate made from, for example, aluminum, an aluminum alloy, or the like. The positive active material layer contains a positive active material. As the positive active material used for the positive active material layer, a material capable of occluding and releasing a lithium ion can be used. Examples of the positive active material include, but are not limited to, LiFePO₄. The positive active material layer may further contain a conductive assistant, a binder, and the like. A region where the positive active material layer is not formed is provided at one end in a width direction of the positive electrode, and the positive electrode current collector 306 is joined to this region.

The negative electrode is an electrode plate in which a negative active material layer is formed on a surface of an elongated strip-shaped negative electrode substrate made from, for example, copper, a copper alloy, or the like. The negative active material layer contains a negative active material. As the negative active material, a material capable of occluding and releasing a lithium ion can be used. Examples of the negative active material include graphite, hard carbon, and soft carbon. The negative active material layer may further contain a binder, a thickener, and the like. A region where the negative active material layer is not formed is provided at another end in a width direction of the negative electrode, and the negative electrode current collector 307 is joined to this region.

The separator is formed of a porous resin film. As the porous resin film, a porous resin film made from resin such as polyethylene (PE) or polypropylene (PP) can be used.

As an electrolyte sealed in a case 82, the same electrolyte as that of a conventional lithium ion secondary battery can be used. For example, an electrolyte in which a supporting electrolyte is contained in an organic solvent can be used as the electrolyte. As the organic solvent, for example, an aprotic solvent such as carbonates, esters, and ethers is used. As the supporting electrolyte, for example, lithium salt such as LiPF₆, LiBF₄, or LiClO₄ is suitably used. The electrolyte may contain, for example, various additives such as a gas generating agent, a film forming agent, a dispersant, and a thickener.

As an example of the battery 30, a prismatic lithium ion battery including the wound electrode assembly 301 is described in FIGS. 3 and 4. Alternatively, the battery 30 may be a lithium ion battery including a stacked electrode assembly, and may be a cylindrical lithium ion battery, a laminated lithium ion battery, or the like. Furthermore, the battery 30 may be an all-solid-state lithium ion battery using a solid as an electrolyte.

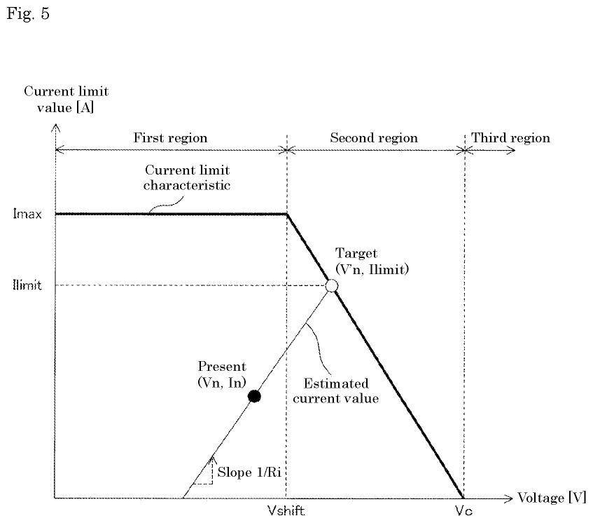

FIG. 5 is a diagram describing a concept of a method of calculating a current limit value in the present embodiment. The method of calculating a current limit value in the present embodiment will be specifically described with reference to FIG. 5. In the graph illustrated in FIG. 5, the vertical axis represents a current limit value (in amperes, [A]), and the horizontal axis represents voltage (in volts, [V]). In FIG. 5, a thick solid line indicates a current limit characteristic of the battery 30. Voltage (voltage value) means maximum battery voltage (maximum terminal voltage) of the battery 30 included in the assembled battery 31.

The current limit characteristic is shown as a function of voltage (voltage value) of the battery 30 and a current limit value. As illustrated in FIG. 5, the current limit characteristic includes a first region where voltage of the battery 30 is from zero to V_{shift}, a second region where voltage of the battery 30 is from V_{shift} to V_{c}, and a third region where voltage of the battery 30 is equal to or more than V_{c}. V_{shift} may be maximum voltage in a region where maximum current Iₘₐₓ allowed for the battery 30 can flow, or may be a fixed value set for each of the batteries 30. V_{c} may be maximum charge voltage allowed for the battery 30, or may be a fixed value set for each of the batteries 30. V_{c} may be CV voltage of CV charge. In the first region in the present embodiment, a current limit value is constant regardless of voltage of the battery 30, and in the second region, a current limit value decreases linearly the voltage of the battery 30 increases. The current limit characteristic is not limited to this form.

The first region in the present embodiment corresponds to a region for CC charge of the battery 30. The second region corresponds to a region in which charge is performed while charge current is lowered as voltage of the battery 30 increases after CC charge. The third region corresponds to a region where charge is temporarily stopped in a case where voltage of the battery 30 becomes equal to or more than the maximum charge voltage V_{c}. The current limit characteristic may be generated in advance for each type of the batteries 30 and stored in the control data 422 of the storage unit 42. In this way, versatility of the BMU 40 is enhanced.

In FIG. 5, a difference between V_{shift} and V_{c} is illustrated to be large for ease of description, but the difference between V_{shift} and V_{c} in an actual current limit characteristic is preferably small (for example, 10 mV or the like). Charge acceptance performance of the battery 30 can be improved by further reducing the difference between V_{shift} and V_{c} in the current limit characteristic, that is, by further narrowing the second region. Alternatively, the difference between V_{shift} and V_{c} in the current limit characteristic may be zero, that is, V_{shift}=V_{c}.

The control unit 41 of the BMU 40 outputs a current limit value identified based on a current limit characteristic to the battery charger 20 at the time of charge-discharge of the battery 30. The control unit 41 calculates a current limit value according to a state of the battery 30 at predetermined intervals. In the first region in the present embodiment, the maximum current Iₘₐₓ is always used as a current limit value regardless of voltage of the battery 30. In the second region, a target current limit value varies depending on voltage of the battery 30. For this reason, the control unit 41 calculates a current limit value of a next stage (next control cycle timing) so as to follow a current limit characteristic based on a current value and a voltage value of the battery 30 at the present.

A current limit value indicated by a current limit characteristic is an upper limit value of charge current. By setting a value on a current limit characteristic to a current limit value of a next stage, it is possible to moderate limitation of charge. For example, charge with power generated by solar power generation can be accepted without excessive restriction for the safety side from the viewpoint of battery protection. In particular, charge characteristics (charge acceptance performance) of the battery 30 can be improved by calculating a current limit value along the second region of a current limit characteristic.

In the present embodiment, the control unit 41 calculates a current limit value by using a current value and a voltage value of the battery 30 at the present (time point of calculation) and internal resistance of the battery 30. The control unit 41 calculates a current limit value of a next stage so that a current value and a voltage value of the battery 30 are equal to a current limit value and a voltage value defined by a current limit characteristic. Specifically, the control unit 41 calculates an intersection of a straight line indicating an estimated current value obtained from a current value and voltage value at the present and a current limit characteristic.

In FIG. 5, a black dot • indicates a plot of voltage Vₙ and current Iₙ at the present (time point of calculation). A thin solid line in FIG. 5 represents a straight line indicating an estimated current value. In FIG. 5, a white point ∘ indicates a plot of an intersection of a current limit characteristic and a straight line indicating an estimated current value.

An estimated current value of the battery 30 can be obtained by an equivalent circuit model of the battery 30. The battery 30 can be, for example, a simplified equivalent circuit model including a constant voltage source connected in series between a positive electrode terminal and a negative electrode terminal, and a DC resistor for simulating an ohmic resistance component (DC resistance component).

The constant voltage source is a voltage source that outputs DC voltage. Voltage output from the constant voltage source is open circuit voltage (OCV) of the battery 30. The OCV is given, for example, as a function of SOC. The DC resistor simulates a DC resistance component (DC impedance) of the battery 30, and includes internal resistance (resistance element) Rᵢ. The internal resistance Rᵢ is given as a value that fluctuates so as to correspond to energizing current, voltage, SOC, temperature, and the like.

The equivalent circuit model can be expressed by Formula (1) below using the terminal voltage Vₙ at the present (time point n of calculation), the present current Iₙ, the internal resistance Rᵢ, and the open circuit voltage OCV of the battery 30.

$$[ Mathematical formula 1 ]$$

$${V}_{n} = OCV + {I}_{n} \times {R}_{i} \qquad ( 1 )$$

When Formula (1) is transformed, Formula (2) below is obtained.

$$[ Mathematical formula 2 ]$$

$${I}_{n} = \frac{1}{{R}_{i}} \times {V}_{n} - \frac{OCV}{{R}_{i}} \qquad ( 2 )$$

As shown in Formula (2), a function formula of the voltage Vₙ and the current Iₙ of the battery 30 can be shown by a straight line having a slope 1/Rᵢ and a point of contact at OCV. In other words, as indicated by a thin solid line in FIG. 5, the voltage Vₙ and the current Iₙ of the battery 30 change along a straight line passing through (Vₙ, Iₙ) and having a slope 1/Rᵢ.

By calculating an intersection between a straight line, which indicates an estimated current value estimated by an equivalent circuit model, and a current limit characteristic, indicated by a white point ∘ in FIG. 5, a current limit value Iₗᵢₘᵢₜ considering a change in voltage and current of the battery 30 is obtained.

The current limit value Iₗᵢₘᵢₜ, which is an intersection of a straight line indicating an estimated current value and a current limit characteristic, and a voltage value V′ₙ corresponding to the current limit value Iₗᵢₘᵢₜ are obtained by Formulas (3) and (4) below, respectively.

$$[ Mathematical formula 3 ]$$

$${I}_{limit} = \frac{{I}_{max} ( {V}_{c} - OCV )}{{R}_{i} \times {I}_{max} + {V}_{c} - {V}_{shift}} \qquad ( 3 )$$

$$[ Mathematical formula 4 ]$$

$${V}_{n}^{′} = \frac{{I}_{max} \times {R}_{i} \times {V}_{c} + OCV \times ( {V}_{c} - {V}_{shift} )}{{R}_{i} \times {I}_{max} + {V}_{c} - {V}_{shift}} \qquad ( 4 )$$

In Formulas (3) and (4), the maximum current Iₘₐₓ, the maximum voltage V_{shift}, and the maximum charge voltage V_{c} are fixed values set in advance for each of the batteries 30. The internal resistance Rᵢ is a value determined based on temperature, SOC, and the like of the battery 30. The control unit 41 stores the internal resistance Rᵢ as, for example, two-dimensional table data of SOC and temperature of a battery in the control data 422 of the storage unit 42, and reads the internal resistance Rᵢ corresponding to temperature and a charge state of the battery 30. The two-dimensional table data of the internal resistance Rᵢ is generated based on, for example, actual measurement data of a battery test. The internal resistance Rᵢ may be, for example, a fixed value such as a maximum value of internal resistance in the battery 30.

Note that the internal resistance Rᵢ may be a parameter that depends only on temperature. The internal resistance Rᵢ may be calculated by sequential operation using an equivalent circuit model.

The open circuit voltage OCV is obtained by Formula (5) below.

$$[ Mathematical formula 5 ]$$

$$OCV = {V}_{n} - {I}_{n} \times {R}_{i} \qquad ( 5 )$$

In Formula (5), measurement data obtained by the voltage detection circuit 43 and the current measurement resistor 52 may be used for the voltage Vₙ and the current Iₙ, respectively.

In a case where the calculated current limit value Iₗᵢₘᵢₜ is larger than the maximum current Iₘₐₓ, the current limit value Iₗᵢₘᵢₜ is changed to the maximum current Iₘₐₓ, and the voltage value V′ₙ is obtained by Formula (6) below instead of Formula (4) above.

$$[ Mathematical formula 6 ]$$

$${V}_{n}^{′} = {I}_{max} \times {R}_{i} + OCV \qquad ( 6 )$$

From the above, the current limit value Iₗᵢₘᵢₜ and the voltage value V′ₙ located on a current limit characteristic can be calculated using measurement data of present voltage, current, temperature, and the like of the battery 30, the internal resistance Rᵢ, the maximum current Iₘₐₓ, the maximum voltage V_{shift}, and the maximum charge voltage V_{c}.

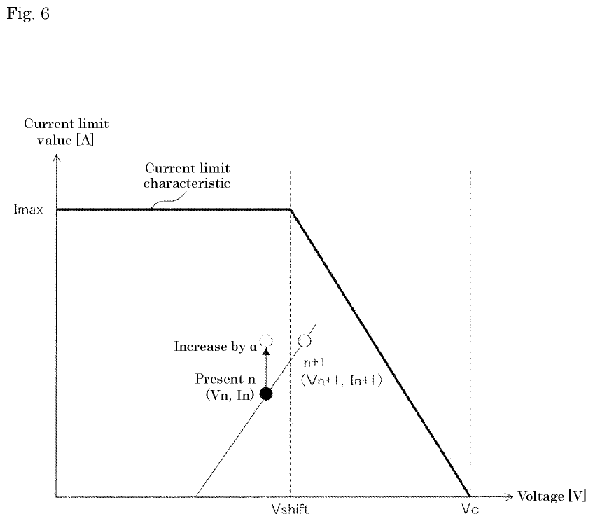

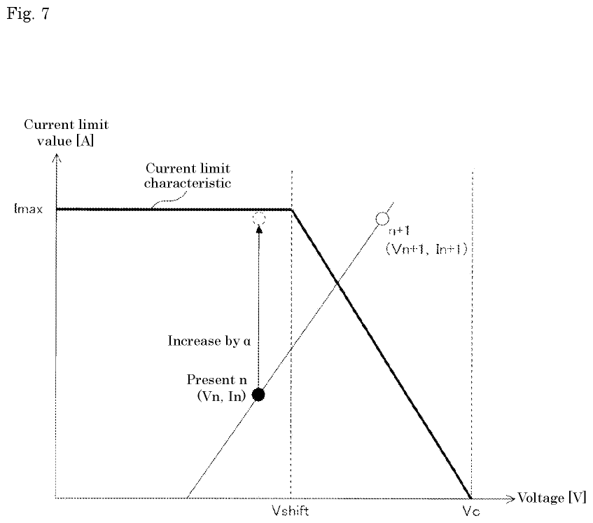

As a comparison, a case where a current limit value is calculated using a predetermined coefficient α set in advance will be described. FIGS. 6 and 7 are diagrams describing a case where a current limit value is calculated using the predetermined coefficient α. FIG. 6 illustrates a case where the predetermined coefficient α is set to a relatively small value. A case where, with respect to the voltage Vₙ and the current Iₙ (black dot • in FIG. 6) at a current time n of the battery 30, a value obtained by adding the predetermined coefficient α to the current Iₙ is set as a current limit value ₗᵢₘᵢₜ will be considered. As illustrated in FIG. 6, when a current value is increased from the current Iₙ by the predetermined coefficient α (a circle indicated by a broken line in FIG. 6), a voltage value also increases as the current value increases. Therefore, voltage Vₙ₊₁ and current Iₙ₊₁ of the battery 30 at a time point of n+1 are shifted in a direction in which voltage increases (white point ∘ in FIG. 6). Here, the current Iₙ₊₁ is equal to the current limit value ₗᵢₘᵢₜ. Since the predetermined coefficient α is relatively small, the voltage Vₙ₊₁ and the current Iₙ₊₁ have values far from a current limit characteristic. In order for approximation to the current limit characteristic, it is necessary to repeat increase of a current limit value in stages.

FIG. 7 illustrates a case where the predetermined coefficient α is set to a relatively large value. As illustrated in FIG. 7, when a current value is increased by the predetermined coefficient α from the current Iₙ, in a case where the predetermined coefficient α is a relatively large value, the voltage Vₙ₊₁ and the current Iₙ₊₁ of the battery 30 at the time point of n+1 are significantly shifted in a direction in which voltage increases. Therefore, the voltage Vₙ₊₁ and the current Iₙ₊₁ may exceed a current limit characteristic. In a case where charge current is limited using the predetermined coefficient α, when the predetermined coefficient α is small, maximum power of the battery 30 cannot be accepted instantaneously, whereas when the predetermined coefficient α is large, the risk of overshoot becomes high and appropriate adjustment is difficult.

According to the method of the present embodiment, based on the voltage Vₙ and the current Iₙ of the battery 30 at the present, a change in a current value and a voltage value in a case where a current limit value is applied is predicted, and then a target value is identified, so that the target value along a current limit characteristic can be suitably calculated.

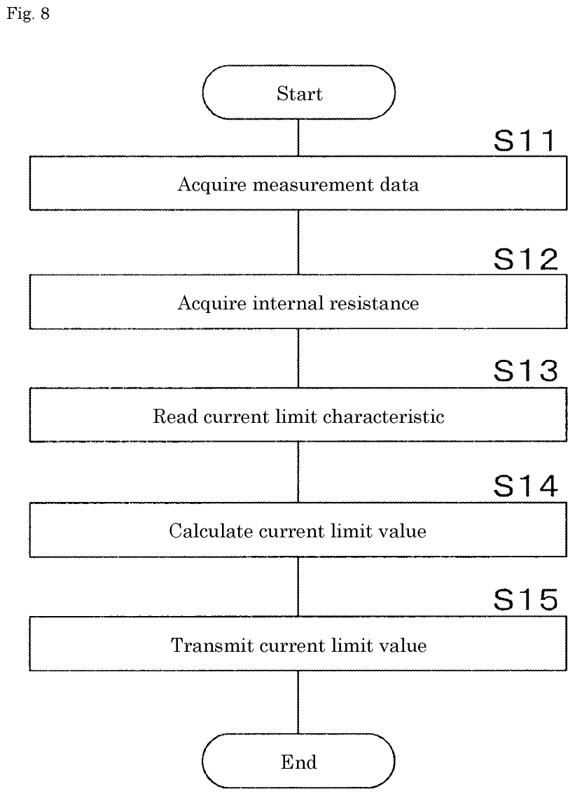

FIG. 8 is a flowchart illustrating an example of a current limit value calculation processing procedure. The control unit 41 of the BMU 40 executes processing below according to the program 421. The control unit 41 may repeatedly execute the processing below at predetermined or appropriate time intervals, for example.

The control unit 41 of the BMU 40 acquires measurement data including the current value Iₙ, the voltage value Vₙ, and temperature of the battery 30 at the present (time point of estimation) through each of the voltage detection circuit 43, the current measurement resistor 52, and the temperature sensor 53 (Step S11). In a case where the BMU 40 is installed at a remote location, the control unit 41 receives measurement data of the battery 30 by communication via the communication unit 45. The control unit 41 functions as an acquisition unit that acquires measurement data including a current value, a voltage value, and temperature.

The control unit 41 acquires the internal resistance Rᵢ of the battery 30 (Step S12). The control unit 41 may acquire the internal resistance Rᵢ by referring to an internal resistance table stored in advance in the control data 422 of the storage unit 42, identifying the internal resistance Rᵢ according to acquired temperature and SOC of the battery 30, and reading the identified internal resistance Rᵢ. The SOC of the battery 30 may be calculated by a current integration method based on, for example, a history of measurement data of the battery 30. The control unit 41 may identify the internal resistance Rᵢ corresponding only to temperature of the battery 30. The control unit 41 may calculate the internal resistance Rᵢ by sequential operation using an equivalent circuit model. The control unit 41 may acquire the internal resistance Rᵢ each time a current limit value is calculated, or may continuously use the internal resistance Rᵢ acquired at a predetermined timing.

The control unit 41 reads a current limit characteristic stored in advance in the control data 422 of the storage unit 42 (Step S13).

The control unit 41 calculates the current limit value Iₗᵢₘᵢₜ based on the current value Iₙ, the voltage value Vₙ, the internal resistance Rᵢ, and the current limit characteristic (Step S14). Specifically, the control unit 41 substitutes the current value Iₙ, the voltage value Vₙ, and the internal resistance Rᵢ into Formulas (3) to (5) described above, and executes arithmetic processing of each formula to calculate an intersection between a straight line, which indicates an estimated current value estimated by an equivalent circuit model, and the current limit characteristic. The control unit 41 calculates the current limit value Iₗᵢₘᵢₜ and the voltage value V′ₙ. The control unit 41 functions as a calculation unit that calculates a current limit value.

In Step S14, in a case where the calculated current limit value Iₗᵢₘᵢₜ is larger than the maximum current Iₘₐₓ, the control unit 41 changes the current limit value Iₗᵢₘᵢₜ to the maximum current Iₘₐₓ, and obtains the voltage value V′ₙ by Formula (6) described above.

The control unit 41 transmits the calculated current limit value Iₗᵢₘᵢₜ to the battery charger 20 (Step S15), and ends a series of pieces of processing. The control unit 41 may transmit the current limit value Iₗᵢₘᵢₜ and the voltage value V′ₙ to the battery charger 20.

The battery charger 20 receives the current limit value Iₗᵢₘᵢₜ. The battery charger 20 controls charge current within a range not exceeding the received current limit value Iₗᵢₘᵢₜ. The battery charger 20 outputs charge current to the battery 30 to charge the battery 30.

In Step S14 described above, the control unit 41 preferably executes verification processing as to whether or not the calculated current limit value Iₗᵢₘᵢₜ and voltage value V′ₙ match the current limit characteristic. This can improve calculation accuracy of the current limit value Iₗᵢₘᵢₜ. The example of calculating the current limit value Iₗᵢₘᵢₜ and the voltage value V′ₙ is described above. Alternatively, the control unit 41 may calculate only the current limit value Iₗᵢₘᵢₜ. By the above, calculation load of the control unit 41 can be reduced.

In the above description, voltage behavior of the battery 30 is simulated by an equivalent circuit model including a DC resistor for simulating an ohmic resistance component. Alternatively, the battery 30 may be represented as an equivalent circuit model including an RC parallel circuit for simulating non-ohmic resistance (transient polarization characteristic) in addition to a DC resistor for simulating an ohmic resistance component. The RC parallel circuit may have one stage or a plurality of stages. As internal resistance including ohmic resistance and non-ohmic resistance is used, estimation accuracy of an estimated current value can be improved.

According to the present embodiment, charge of the battery 30 can be controlled by a current limit value on a current limit characteristic. Charge using a maximum current value allowed for the battery 30 becomes possible instantaneously, and charge characteristics of the battery 30 can be improved.

### Second Embodiment

In a second embodiment, the internal resistance Rᵢ is corrected using a correction coefficient. Hereinafter, the above difference will be mainly described. Since the other configurations are similar to those of the first embodiment, the same reference signs are given to the common configurations, and detailed description of the configurations will be omitted.

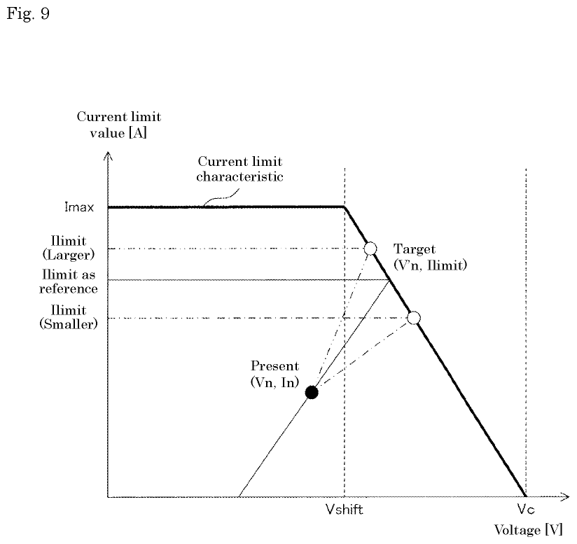

FIG. 9 is a diagram describing a concept of a method of calculating a current limit value in the second embodiment. For example, since the internal resistance Rᵢ used for calculation of a current limit value is different from actual internal resistance of the battery 30, an actual current value and voltage value when the current limit value Iₗᵢₘᵢₜ is allowed to flow may not match a current limit characteristic, and may be higher or lower than the predicted voltage value V′ₙ. Further, for example, depending on a length of a communication interval between the BMU 40 and the battery charger 20, a charge control speed in the battery charger 20, and the like, also in a case where it takes time until a current limit value output by the BMU 40 is applied, an actual current value and voltage value are predicted not to match a current limit characteristic. By making the current limit value Iₗᵢₘᵢₜ smaller or larger than a basic value in advance in consideration of deviation of internal resistance and a response delay, an actual current value and voltage value can be approximated to a current limit characteristic.

As described in the first embodiment, the current limit value Iₗᵢₘᵢₜ can be calculated as an intersection of a straight line indicating an estimated current value estimated by an equivalent circuit model and a current limit characteristic. The straight line indicating an estimated current value has a slope of 1/Rᵢ. By multiplying the internal resistance Rᵢ by a correction coefficient k, as indicated by an alternate long and short dash line or an alternate long and two short dashes line in FIG. 9, a slope of the straight line indicating an estimated current value can be made smaller or larger than that in case where the internal resistance Rᵢ is not corrected. The current limit value Iₗᵢₘᵢₜ can be made smaller or larger than that in a case where the internal resistance Rᵢ is not corrected. The control unit 41 of the BMU 40 acquires the correction coefficient k corresponding to a state of the battery 30 in advance and stores the correction coefficient k in the control data 422 of the storage unit 42. An appropriate value is set to the correction coefficient k based on the degree of increase or decrease of a current limit value with respect to the battery 30, for example, according to deviation of internal resistance or a response delay.

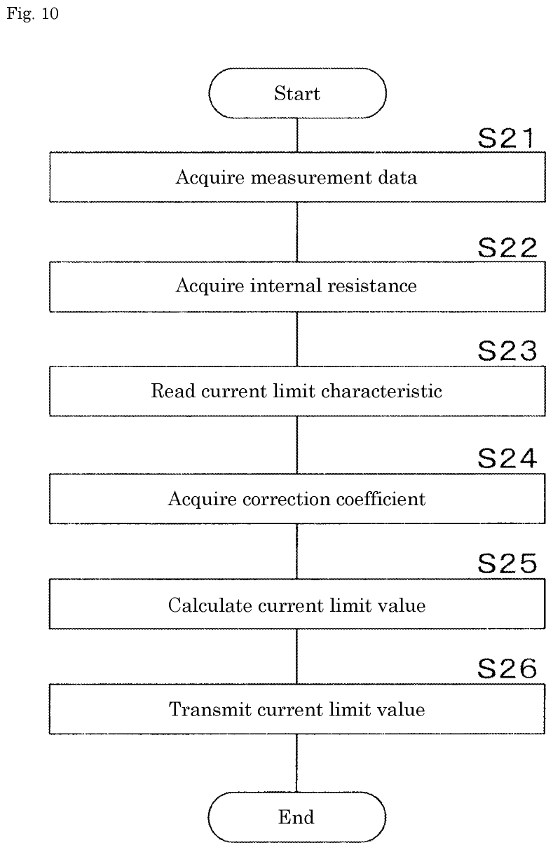

FIG. 10 is a flowchart illustrating an example of a current limit value calculation processing procedure in the second embodiment. The control unit 41 of the BMU 40 acquires the measurement data of the battery 30 at the present (Step S21). The control unit 41 acquires the internal resistance Rᵢ identified based on an internal resistance table (Step S22). The control unit 41 reads a current limit characteristic (Step S23). The processing in Steps S21 to S23 is similar to that in Steps S11 to S13 illustrated in FIG. 8.

The control unit 41 acquires the correction coefficient k by reading the correction coefficient k from the control data 422 of the storage unit 42 (Step S24). The control unit 41 calculates a current limit value (Step S25). In calculating the current limit value Iₗᵢₘᵢₜ and the voltage value V′ₙ, the control unit 41 performs calculation by using a value obtained by multiplying the internal resistance Rᵢ identified based on the internal resistance table by the correction coefficient k. The control unit 41 can calculate the current limit value Iₗᵢₘᵢₜ and the voltage value V′ₙ in consideration of the correction coefficient k. The control unit 41 may correct the internal resistance Rᵢ by adding or subtracting the correction coefficient k to or from the internal resistance Rᵢ.

The control unit 41 transmits the calculated current limit value Iₗᵢₘᵢₜ to the battery charger 20 (Step S26), and ends a series of pieces of processing.

According to the present embodiment, a speed of increasing or decreasing the current limit value Iₗᵢₘᵢₜ can be adjusted by correcting the internal resistance Rᵢ by using the correction coefficient k. Charge can be suitably controlled in consideration of a change in the internal resistance Rᵢ and a response delay of the battery charger 20.

### Third Embodiment

In a third embodiment, a correction coefficient of the internal resistance Rᵢ is changed according to a current value and a voltage value of the battery 30. Hereinafter, the above difference will be mainly described. Since the other configurations are similar to those of the first embodiment and the second embodiment, the same reference signs are given to the common configurations, and detailed description of the configurations will be omitted.

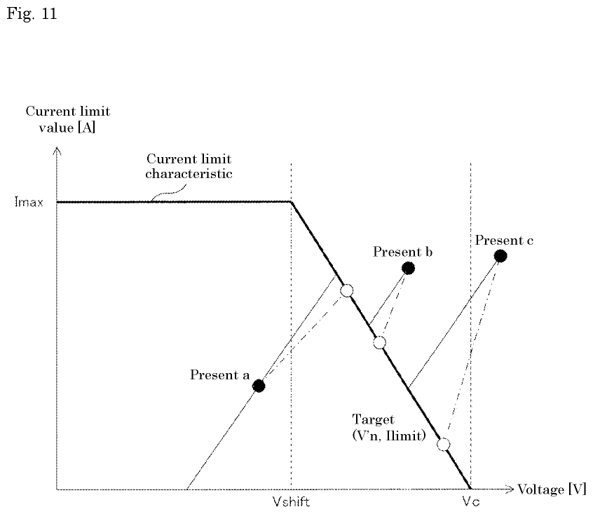

FIG. 11 is a diagram describing a concept of a method of calculating a current limit value in the third embodiment. In a case where the internal resistance Rᵢ is corrected by the correction coefficient k, it is preferable to change the correction coefficient k according to a current value or a voltage value of the battery 30 at the present.

As illustrated in FIG. 11, for example, in a case of a present a where a current value and a voltage value of the battery 30 are further on the lower side than a current limit characteristic (a current value and a voltage value of the battery 30 are smaller than a limited current value and a voltage value of the current limit characteristic), the current limit value Iₗᵢₘᵢₜ that slowly approaches a target value is calculated. A correction coefficient ka is selected so as to reduce a slope of a straight line indicating an estimated current value. In a case of a present b where a current value and a voltage value of the battery 30 are further on the upper side than the current limit characteristic (a current value and a voltage value of the battery 30 are larger than a limited current value and a voltage value of the current limit characteristic), the current limit value Iₗᵢₘᵢₜ that quickly approaches a target value is calculated. A correction coefficient kb is selected so as to increase a slope of a straight line indicating an estimated current value. In a case of a present c where a current value and a voltage value of the battery 30 are further on the upper side than the current limit characteristic and a voltage value is also equal to or more than a maximum charge voltage V_{c}, the current limit value Iₗᵢₘᵢₜ that more quickly approaches a target value is calculated. A correction coefficient kc is selected so as to further increase a slope of a straight line indicating an estimated current value. As an example, for example, in a case where internal resistance of the battery 30 when it is brand new is used as a reference, the correction coefficient ka for the present a may be 1.5, the correction coefficient kb for the present b may be 1.0, and the correction coefficient kc for the present c may be 0.5.

The control unit 41 of the BMU 40 acquires a correction coefficient table in which a state of a current value and a voltage value of the battery 30 are associated with the correction coefficient k representing a speed of increasing or decreasing a current limit value in advance, and stores the correction coefficient table in the control data 422 of the storage unit 42. A plurality of the correction coefficients k may be set according to a state of a current value and a voltage value of the battery 30, for example, for a case where the current value and the voltage value of the battery 30 are further on the upper side than a current limit characteristic, for a case where the current value and the voltage value of the battery 30 are further on the lower side than the current limit characteristic, and the like. Alternatively, a plurality of the correction coefficients k may be set according to a current value of the battery 30, for example.

In calculating the current limit value Iₗᵢₘᵢₜ and the voltage value V′ₙ, the control unit 41 performs calculation by using a value obtained by multiplying the internal resistance Rᵢ identified based on the internal resistance table by the correction coefficient k. In this case, the control unit 41 refers to a correction coefficient table and acquires the correction coefficient k corresponding to a current value and a voltage value of the battery 30 at the present. More specifically, the control unit 41 compares a magnitude relationship between a current value and a voltage value of the battery 30 at the present and a current limit characteristic, and selects the correction coefficient k according to a comparison result. The control unit 41 may acquire the correction coefficient k according to a current value of the battery 30 at the present.

According to the present embodiment, the speed of increasing or decreasing the current limit value Iₗᵢₘᵢₜ can be adjusted by changing the correction coefficient k according to the current value or the current value and the voltage value of the battery 30. Charge can be more suitably controlled in consideration of the state of the current value or the current value and the voltage value of the battery 30 with respect to the current limit characteristic.

In the above embodiment, the energy storage apparatus 10 including the management apparatus 40 is applied to a solar power generating system. The management apparatus, the management method, and the program may be applied to other facilities, vehicles (for example, an automobile, a two-wheeled vehicle, a railway vehicle, an industrial vehicle, and the like), industrial devices (for example, for aviation, space, marine, harbor, and the like), power supply devices, and the like.

In the above embodiment, the energy storage apparatus 10 in which one of the assembled battery 31 is managed by the management apparatus 40 is used. Alternatively, a bank in which a plurality of assembled batteries (modules) in which a plurality of batteries are connected in series are connected in series and a management apparatus that manages the bank may be included. The management apparatus may be a simple management apparatus (cell monitoring device: CMU) that acquires measurement data and transmits the data to a high-order control device.

It is to be understood that the embodiments disclosed herein are illustrative in all respects and not restrictive. The technical features described in examples can be combined with each other, and the scope of the present invention is intended to include all modifications within the claims and the scope equivalent to the claims.

1. A management apparatus comprising:
an acquisition unit that acquires a current value and a voltage value of an energy storage device; and
a calculation unit that calculates a current limit value along a current limit characteristic of the energy storage device based on internal resistance of the energy storage device and the acquired current value and voltage value.

2. The management apparatus according to claim 1, wherein
the current limit characteristic includes a first region, and a second region in which the current limit value decreases in accordance with increase in a voltage value of the energy storage device, and
the calculation unit calculates the current limit value along the second region of the current limit characteristic.

3. The management apparatus according to claim 1, wherein the calculation unit calculates, as the current limit value, a value at which the current limit characteristic intersects an estimated current value, which is estimated based on the current value, the voltage value, and the internal resistance by using an equivalent circuit model of the energy storage device.

4. The management apparatus according to claim 1, wherein the calculation unit calculates the current limit value based on the internal resistance corresponding to at least one of a charge state and temperature of the energy storage device.

5. The management apparatus according to claim 1, wherein the calculation unit calculates the current limit value based on the internal resistance corrected using a correction coefficient.

6. The management apparatus according to claim 5, wherein the correction coefficient is changed according to the current value.

7. The management apparatus according to claim 5, wherein the correction coefficient is changed based on a result of comparison between the acquired current value and voltage value of the energy storage device and the current limit characteristic of the energy storage device.

8. An energy storage apparatus comprising:
an energy storage device; and
the management apparatus according to claim 1.

9. A management method in which a computer executes processing of:
acquiring a current value and a voltage value of an energy storage device; and
calculating a current limit value along a current limit characteristic of the energy storage device based on internal resistance of the energy storage device and the acquired current value and voltage value.

10. A program for causing a computer to execute processing of:
acquiring a current value and a voltage value of an energy storage device; and
calculating a current limit value along a current limit characteristic of the energy storage device based on internal resistance of the energy storage device and the acquired current value and voltage value.
